(19) United States
(12) Patent Application Publication
(10) Pub. No.: US 2007/0243327 A1
(43) Pub. Date: Oct. 18, 2007

(54) Film forming method and apparatus

(76) Inventors: Song Yun Kang, Amagasaki-Shi (JP); Tamotsu Morimoto, Nirasaki-Shi (JP); Yoshihiro Kato, Nirasaki-Shi (JP)

Correspondence Address: Smith, Gambrell & Russell, Suite 800, 1850 M Street, N.W., Washington, DC, 20036, US

(21) Appl. No.: 11/638,672

(22) Filed: Dec. 14, 2006

(30) Foreign Application Priority Data
Dec. 15, 2005 (JP) 2005-362100

(51) Int. Cl. C23C 16/40

(52) U.S. Cl. 427/255.29; 118/715

(57) ABSTRACT

In the film forming method of the present invention, a substrate is first received in a processing vessel. Then, a film-forming gas including an organic silicon and an additive gas including a paraffin hydrocarbon gas and/or a hydrogen gas are introduced into the processing vessel, and the film-forming gas and the additive gas are then converted into plasma. In this manner, a carbon-hydrogen-added silicon oxide film (SiCOH film) is formed on the substrate. Alternatively, the film-forming gas is first introduced into the processing vessel containing the substrate and is then converted into plasma to form the SiCOH film on the substrate. Subsequently, the additive gas is introduced into the processing vessel and is then converted into plasma to post-treat the substrate having the SiCOH film formed thereon.

### BACKGROUND OF THE INVENTION

1. Field of the Invention

The present invention relates to a film forming method of a carbon-hydrogen-added silicon oxide film which is used, for example, as an interlayer dielectric (insulation) film, and to a film forming apparatus for performing such a film forming method.

2. Description of Related Art

As a typical example of interlayer dielectric films for semiconductor devices, a silicon dioxide film (SiO₂ film) is known. In recent years, there is need for lowering a dielectric constant of the interlayer dielectric film in order to accelerate operation of devices. Due to such a demand, a carbon (C)-hydrogen (H)-added silicon oxide film (hereinafter, referred to as a “SiCOH film”) has attracted attention. While the dielectric constant of the SiO₂ film is around 4, the SiCOH film exhibits the dielectric constant of 2.5 or less and has sufficient mechanical strength, as such providing a quite useful film as the interlayer dielectric film.

A technology for forming the SiCOH film by using a six-membered or eight-membered cyclic siloxane as a precursor while introducing an excitation gas into a processing vessel is described in, for example, WO 03/019645 A1. In such a manner, if it is possible to remain Si—O cyclic structures contained in a raw material in the film, by using a cyclic-structured siloxane precursor, the resultant SiCOH film would be a low-density porous film, thus reducing the dielectric constant of the film

In light of the above, the inventors have studied a method of forming the SiCOH film having such a low dielectric constant and have noted a six-membered cyclic siloxane precursor shown in FIG. 13 as a raw material gas. The six-membered cyclic siloxane precursor is obtained by coupling alkyl groups or vinyl groups as R1, R2 to a six-membered siloxane cyclic structure.

When performing a plasma process under predetermined conditions by using such a six-membered cyclic siloxane precursor, the alkyl groups or the like coupled to the Si—O cyclic structure of each siloxane are disscociated by plasma, and radicals having dangling bonds are generated in a gas phase in large numbers. Due to such radicals serving as a precursor, the SiCOH film is formed by a chain of coupling between the dangling bonds while leaving their cyclic structures in the film.

However, even in the case of forming the SiCOH film by using the six-membered cyclic siloxane precursor as a raw material in such a manner, the dielectric constant can not be lowered as expected. Eventually, properties of the SiCOH film as the interlayer dielectric film are deteriorated due to a large leak current thereof. This is because, while the SiCOH film is formed due to the radicals each having a cyclic structure and serving as the precursor, since a great number of Si dangling bonds are still present in the film, a gap of electronic energy becomes smaller, and this may cause increase of the leak current.

### SUMMARY OF THE INVENTION

The present invention was made under such circumstances, and therefore, it is an object of this invention to provide a technology which can form a carbon-hydrogen-added silicon oxide film exhibiting a lower dielectric constant and a reduced leak current.

In order to achieve the object above, the present invention provides a film forming method comprising the steps of:

placing a substrate in a processing vessel; and

forming a carbon-hydrogen-added silicon oxide film on the substrate, by introducing a film-forming gas including an organic silicon and an additive gas including a paraffin hydrocarbon gas and/or a hydrogen gas (at least one of the paraffin hydrocarbon gas and the hydrogen gas) into the processing vessel, and converting the film-forming gas and the additive gas into plasma.

From another viewpoint, the present invention provides a film forming apparatus comprising:

a processing vessel that receives a substrate therein;

a film-forming gas supply system configured to supply a film-forming gas including an organic silicon into the processing vessel;

an additive gas supply system configured to supply an additive gas including a paraffin hydrocarbon gas and/or a hydrogen gas into the processing vessel;

a plasma generating system configured to generate plasma in the processing vessel; and

a controller configured to control the film-forming gas supply system, the additive gas supply system, and the plasma generating system, to form a carbon-hydrogen-added silicon oxide film on the substrate, by introducing the film-forming gas and the additive gas into the processing vessel and converting those gases into plasma.

According to the method and the apparatus, Si dangling bonds present in the carbon-hydrogen-added silicon oxide film are terminated by coupling of the Si dangling bonds with C or H dangling bonds generated by converting the additive gas into plasma. Therefore, since the Si dangling bonds present in the film are reduced, leak current attributed to the Si dangling bonds in the film can be suppressed, thereby to obtain the carbon-hydrogen-added silicon oxide film which exhibits a significantly lower dielectric constant.

Alternatively, the present invention provides a film forming method comprising the steps of:

placing a substrate in a processing vessel;

forming a carbon-hydrogen-added silicon oxide film on the substrate, by introducing a film-forming gas including an organic silicon into the processing vessel, and converting the film-forming gas into plasma;

post-treating the substrate having the carbon-hydrogen-added silicon oxide film formed thereon, by introducing an additive gas including a paraffin hydrocarbon gas and/or a hydrogen gas into the processing vessel, and converting the additive gas into plasma.

From another viewpoint, the present invention provides a film forming apparatus comprising:

a processing vessel that receives a substrate therein;

a film-forming gas supply system configured to supply a film-forming gas including an organic silicon into the processing vessel;

an additive gas supply system configured to supply an additive gas including a paraffin hydrocarbon gas and/or a hydrogen gas into the processing vessel;

a plasma generating system configured to generate plasma in the processing vessel; and

a controller configured to control the film-forming gas supply system, the additive gas supply system, and the plasma generating system, to form a carbon-hydrogen-added silicon oxide film on the substrate, by introducing the film-forming gas into the processing vessel and converting the film-forming gas into plasma, and then post-treat the substrate having the carbon-hydrogen-added silicon oxide film formed thereon, by introducing the additive gas into the processing vessel and converting the additive gas into plasma.

The present invention also provides a film forming method comprising the steps of:

placing a substrate in a first processing vessel;

forming a carbon-hydrogen-added silicon oxide film on the substrate, by introducing a film-forming gas including an organic silicon into the first processing vessel, and converting the film-forming gas into plasma;

placing the substrate having the carbon-hydrogen-added silicon oxide film formed thereon in a second processing vessel;

post-treating the substrate having the carbon-hydrogen-added silicon oxide film formed thereon, by introducing an additive gas including a paraffin hydrocarbon gas and/or a hydrogen gas into the second processing vessel, and converting the additive gas into plasma.

Namely, the step of forming the carbon-hydrogen-added silicon oxide film and the step of the post-treatment may be carried out in different processing vessels, respectively.

According to the method and the apparatus, the C dangling bonds and/or H dangling bonds generated by the plasma of the post-treatment penetrate into the porous carbon-hydrogen-added silicon oxide film to be coupled with the Si dangling bonds present in the carbon-hydrogen-added silicon oxide film. Consequently, since the Si dangling bonds present in the film are reduced, thereby to obtain the carbon-hydrogen-added silicon oxide film which exhibits a lowered dielectric constant and reduced leak current.

As the film-forming gas including an organic silicon, a gas having a cyclic structure of a siloxane can be used. The carbon-hydrogen-added silicon oxide film comprises the cyclic structure of, for example, the siloxane.

### BRIEF DESCRIPTION OF THE DRAWINGS

FIG. 1 is a schematic diagram showing one embodiment of a film forming method of the present invention;

FIG. 2 is a diagram showing operation of the film forming method of the present invention, by using chemical structural formulae;

FIG. 3 is a diagram showing operation of the film forming method of the present invention, by using chemical structural formulae;

FIG. 4 is a diagram showing operation of the film forming method of the present invention, by using chemical structural formulae;

FIG. 5 is a schematic diagram showing another embodiment of the film forming method of the present invention;

FIG. 6 is a schematic diagram showing another embodiment of the film forming method of the present invention;

FIG. 7 is a cross section showing a structure of a MOS transistor, in which the SiCOH film according to the present invention is used;

FIG. 8 is a cross section showing one example of a film forming apparatus for implementing the film forming method of the present invention;

FIG. 9 is a plan view showing a gas supply member used in the apparatus of FIG. 8;

FIGS. 10A and 10B are graphs respectively showing results of experiments which were carried out for confirming an effect of the film forming method of the present invention;

FIG. 11 is a graph showing a result of simulation which was carried out for confirming an effect of the film forming method of the present invention;

FIG. 12 is a diagram showing a result of simulation which was carried out for confirming an effect of the film forming method of the present invention; and

FIG. 13 is a chemical formula illustrating a gas having a six-membered siloxane cyclic structure.

### DESCRIPTION OF THE PREFERRED EMBODIMENT

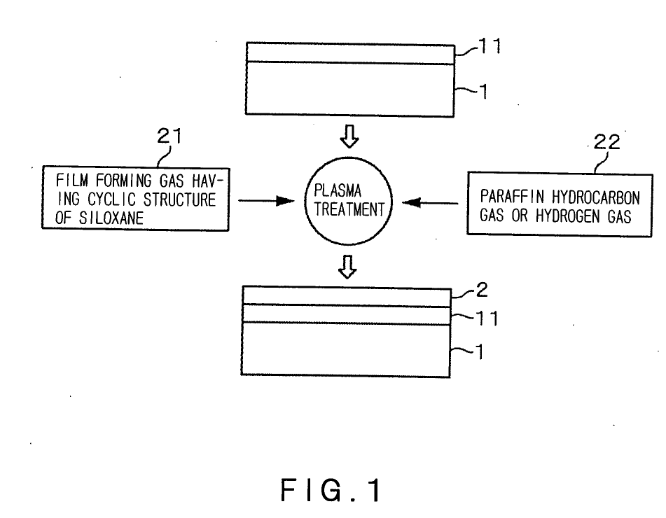

The film forming method of the present invention is intended to form an interlayer dielectric film comprising a carbon-hydrogen-added silicon oxide film (SiCOH film), and this film forming method is schematically shown in FIG. 1. As a substrate 1, for example, a substrate having a BPSG film 11 formed on its surface is used, this substrate being for use in forming, for example, an integrated circuit including a CMOS. The BPSG film 11 is a silicate glass film doped with boron (B) and phosphorus (P). In lieu of the BPSG film 11, a silicon oxide film may be used, which is formed by using a TEOS as a raw material.

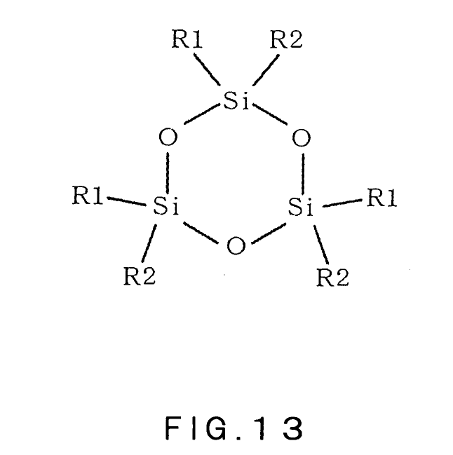

As a film-forming gas 21, a film-forming gas including an organic silicon, for example, a siloxane gas having a cyclic structure is used. The siloxane gas includes those created by coupling an alkyl group, such as a methyl group (-CH₃) as R1 and a vinyl group (—CH₂═CH₂) as R2, to a six-membered siloxane cyclic structure, as shown in FIG. 13 (hereinafter, this siloxane gas will be referred to as a “siloxane gas A”).

Other than the film-forming gas 21, an additive gas 22 including a paraffin hydrocarbon (CₙH₂ₙ₊₂) gas and/or a hydrogen (H₂) gas (at least one of the paraffin hydrocarbon gas and the hydrogen gas) is used. As the paraffin hydrocarbon, methane (CH₄) or ethane (C₂H₆) can be used.

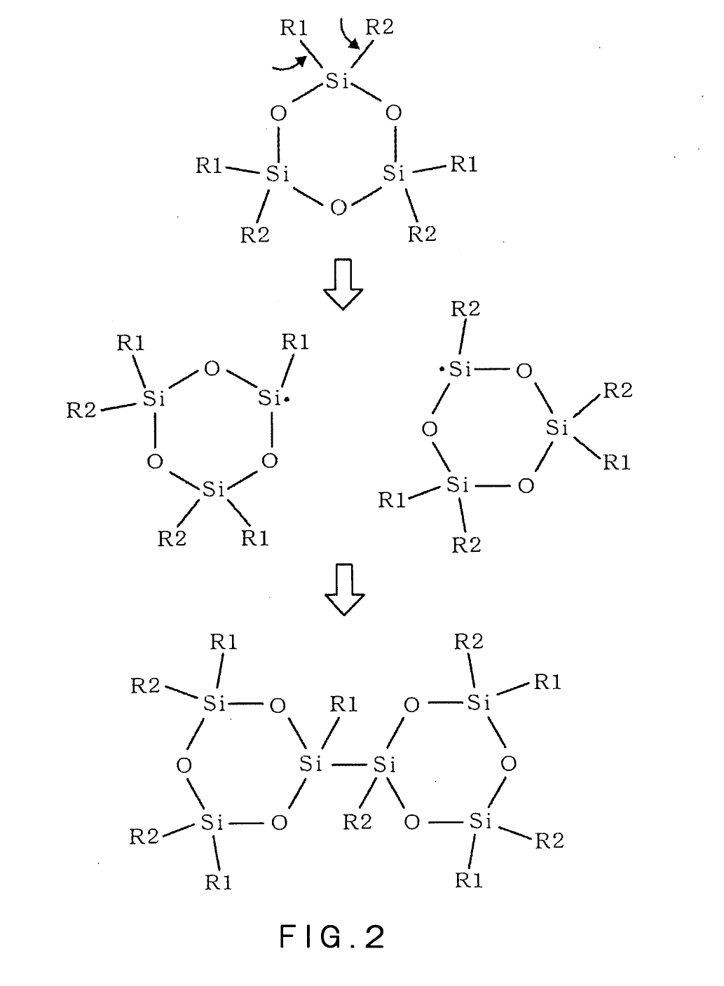

Herein, by way of example, the case of forming the SiCOH film by using the siloxane gas A as the film-forming gas and the methane gas as the additive gas will be described. When the siloxane gas A is converted into plasma under predetermined conditions, for example, as shown in FIG. 2, a coupling (Si—R1 coupling) between Si and R1 (methyl group) each constituting the cyclic structure of the siloxane (Si—O cyclic structure) and/or a coupling (Si—R2 coupling) between Si and R2 (vinyl group) each constituting the cyclic structure is disconnected, as such R1 and/or R2 is detached so as to make the Si constituting the cyclic structure be a dangling bond. In this manner, radicals having such dangling bonds (Si.) are generated in a gas phase in large numbers.

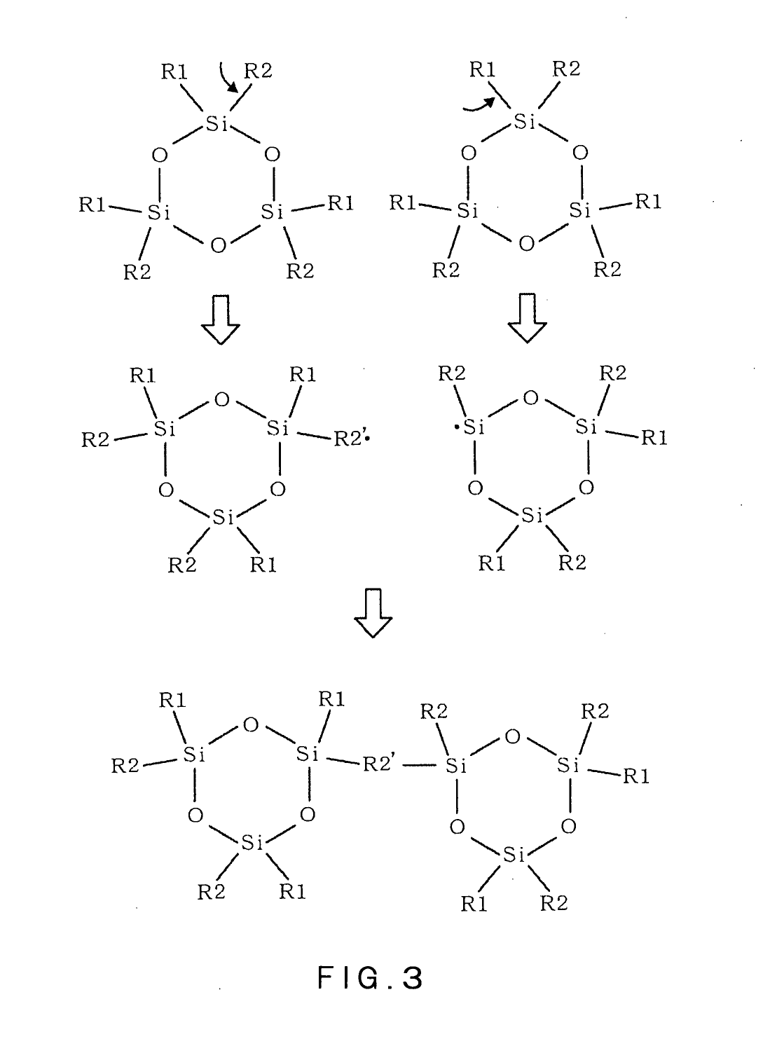

Alternatively, as shown in FIG. 3, other siloxane radicals having C dangling bonds due to radicals (R2′.(—CH₂═CH.)) in each of which H (hydrogen) is removed from R2 (vinyl group) and/or C dangling bonds due to radicals (R1′.(—CH₂.)) (not shown) in each of which H (hydrogen) is removed from R1 (methyl group) are also generated in the gas phase in large numbers.

Thereafter, such Si dangling bond radicals, each constituting the cyclic structure of the siloxane, are coupled together, or the Si dangling bond and the C dangling bond are coupled to each other, or otherwise the C dangling bonds are coupled together, and further linked three-dimensionally so as to form an SiCOH film 2. Since the SiCOH film 2 is formed in a state where each cyclic structure of the siloxane is maintained, it has a porous structure. With respect to the dangling bonds present in the SiCOH film, the Si dangling bonds remain as unbonded sites because they are relatively stable, while the C dangling bonds are readily coupled to other radicals having the Si dangling bonds because they are active and thus almost all of them are lost in the film.

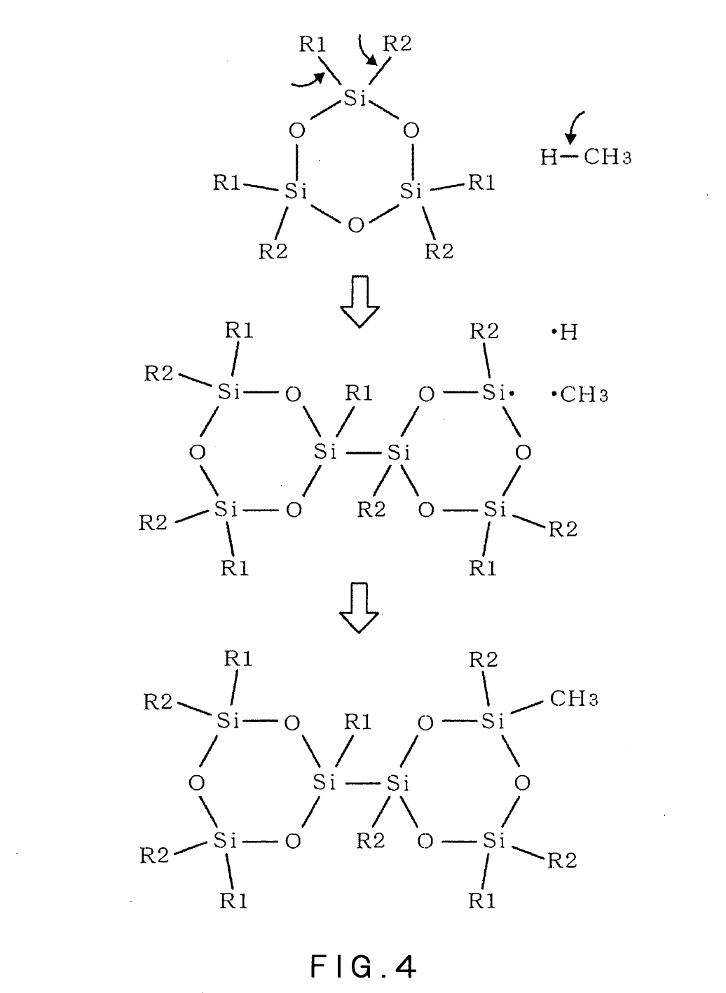

On the other hand, when the methane gas is converted into plasma under predetermined conditions, as shown in FIG. 4, a C-H coupling is disconnected, so that a dangling bond of CH₃ (.CH₃) and/or a dangling bond of H (.H) is generated. Thereafter, since these dangling bonds are coupled to each Si dangling bond in the SiCOH film 2, the Si dangling bonds present in the film are reduced.

This method is intended to form the SiCOH film 2 by converting the film-forming gas, such as the siloxane gas A, and the additive gas, such as the methane gas, into plasma. However, in order to form the SiCOH film 2 comprising the cyclic structure of the siloxane, it is necessary to generate the dangling bond radicals by applying energy such that, without breaking each cyclic structure of the siloxane gas A, the energy can disconnect the coupling between Si and R1 and/or coupling between Si and R2 of each siloxisane and remove the hydrogen from the methyl group and/or vinyl group, as well as it can also disconnect the C—H coupling of the additive gas. Accordingly, plasma conditions for applying such energy and a type of the additive gas should be selected critically.

It is also necessary that the additive gas is supplied in an amount required for terminating the Si dangling bonds in the film. For example, it is preferred that the additive gas is added in a ratio of approximately 5 mol % to 200 mol %, more preferably in the ratio of approximately 5 mol % to 30 mol %, relative to the film-forming gas. If the ratio exceeds 200 mol %, the film forming rate is reduced, while if the ratio is lower than 5 mol %, an effect of reducing the Si dangling bonds can not be obtained.

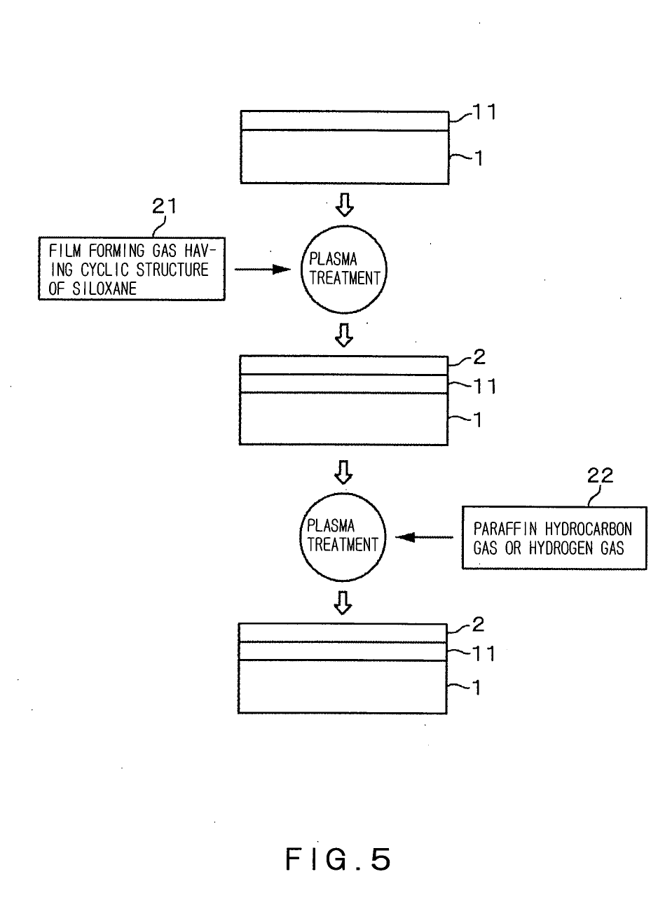

Next, another embodiment of the film forming method of the present invention will be described with reference to FIG. 5. In FIG. 5, by initially converting the siloxane film-forming gas 21 having the cyclic structure of the siloxane gas A previously described into plasma, the SiCOH film 2 is formed on a substrate. Subsequently, the additive gas 22, which comprises a paraffin hydrocarbon gas and/or a hydrogen gas and is converted into plasma, is irradiated to the SiCOH film 2 so as to perform a post-treatment. Consequently, the SiCOH film 2 including substantially reduced dangling bonds can be obtained.

The step of irradiating the plasma generated from the additive gas 22 to the SiCOH film 2 is carried out by introducing the additive gas 22 into a processing vessel containing a wafer W having the SiCOH film formed thereon, and converting the additive gas into plasma. As the processing vessel, the reaction vessel (first processing vessel) for converting the film-forming gas into plasma to form the SiCOH film 2 may be used, or alternatively, another reaction vessel (second processing vessel) may also be used.

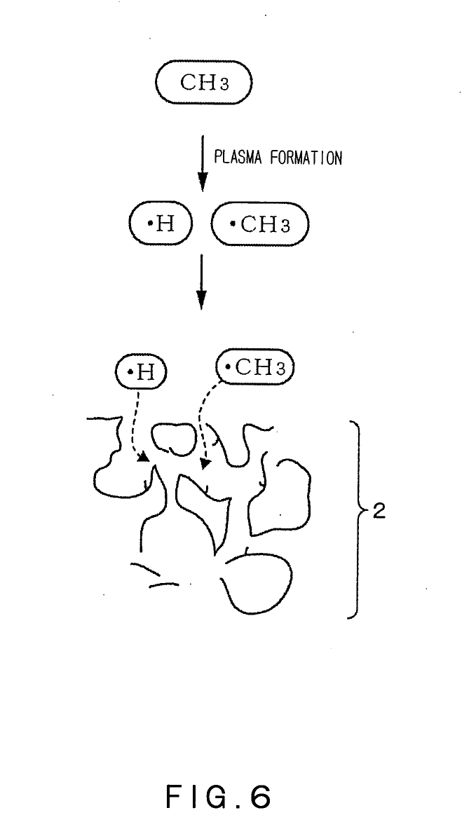

Also by separately carrying out the post-treatment as described above, the Si dangling bonds contained in the SiCOH film 2 can be terminated by the C dangling bonds and/or H dangling bonds created by such a plasma generating process using the additive gas. Namely, as previously described, the SiCOH film 2 is porous since the dangling bonds are coupled together in a state where the cyclic structure of the siloxane is maintained as it is. Additionally, the cyclic structure of the siloxane is relatively large because it is a six-membered cyclic. Therefore, spaces defined between elements constituting such a porous structure are relatively large, and as shown in FIG. 6, the C dangling bonds and/or H dangling bonds created by the plasma generating process using the additive gas can penetrate into such spaces and be coupled to the Si dangling bonds present in the interior of the film.

Also, in this case, in order to form the SiCOH film having the cyclic structure of the siloxane, the film forming process of the SiCOH film 2 is carried out under plasma conditions to apply energy such that, without breaking each cyclic structure of the siloxane gas A, the energy can disconnect the coupling between Si and R1 and/or coupling between Si and R2 of each siloxisane and remove the hydrogen from the methyl group and/or vinyl group. In the post-treatment, a process for terminating the Si dangling bonds is carried out under plasma conditions to provide energy to disconnect the C—H bonds in the additive gas. Additionally, it is necessary to add the additive gas in an amount required for terminating the Si dangling bonds in the film. For example, the additive gas is preferably added in a ratio of approximately 5 mol % to 200 mol %, more preferably in the ratio of approximately 5 mol % to 30 mol %, relative to the film-forming gas. If the ratio exceeds 200 mol %, the film would be damaged, while if the ratio is lower than 5 mol %, an effect of reducing the Si dangling bonds can not be obtained.

As described above, in the SiCOH film 2 formed in accordance with the method of this invention, the Si dangling bonds present in the film are terminated due to their coupling with the C or H dangling bonds, as such the Si dangling bonds present in the film are reduced. Accordingly, generation of the leak current attributed to the presence of the Si dangling bonds in the film can be suppressed, thereby securing a lower dielectric constant and achieving more preferred properties as the interlayer dielectric film.

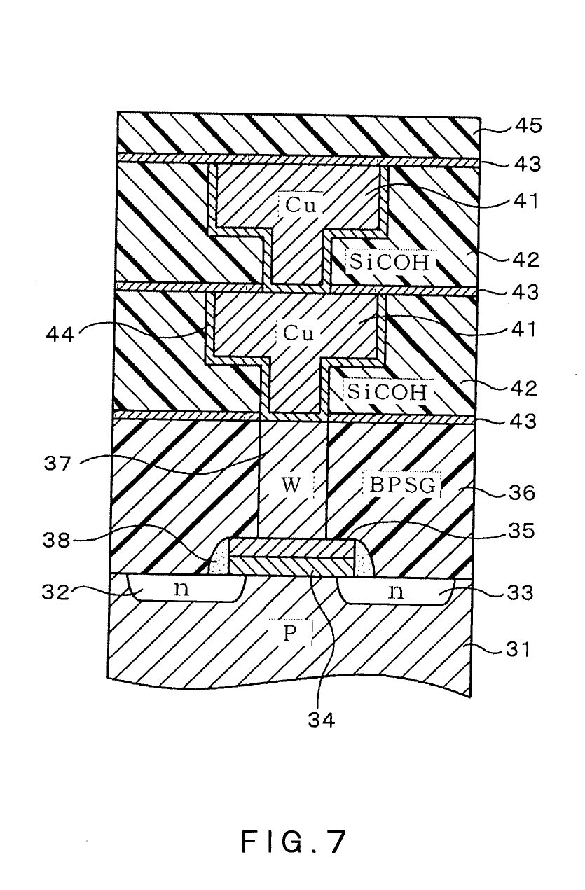

FIG. 7 shows one example of semiconductor devices, which includes the interlayer dielectric film formed as described above, wherein reference numeral 31 designates a p-type silicon layer, 32 and 33 denote n-type regions constituting a source and a drain, respectively, 34 is a gate oxide film, and 35 designates a gate electrode, and a MOS transistor is composed of those elements. In addition, reference numeral 36 is a BPSG film, 37 designates a wiring formed from, for example, tungsten (W), and 38 denotes a side spacer. On the BPSG film 36, inter layer dielectric films 42 are stacked in a multi-layered fashion, which are each formed of the SiCOH film of the present invention and in which wiring layers 41 formed from, for example, copper (Cu) are embedded, respectively (for convenience, two layers are shown in FIG. 6). Additionally, reference numeral 43 denotes a hard mask formed from, for example, silicon nitride, 44 is a protective layer formed from, for example, titanium nitride or tantalum nitride, for preventing diffusion of the wiring metal, and 45 designates a protective film.

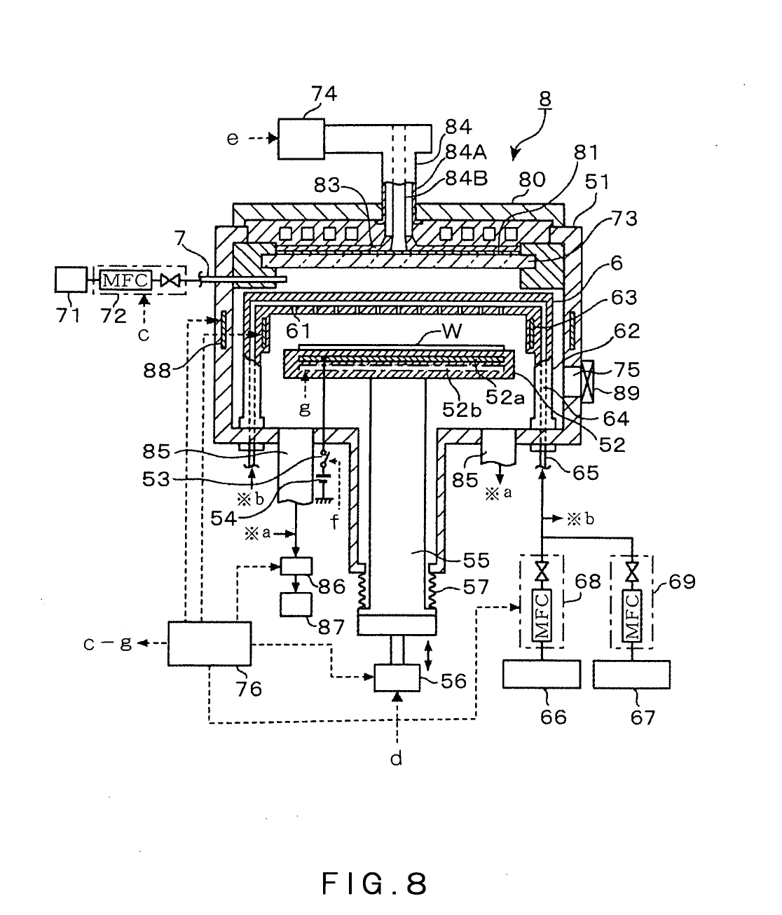

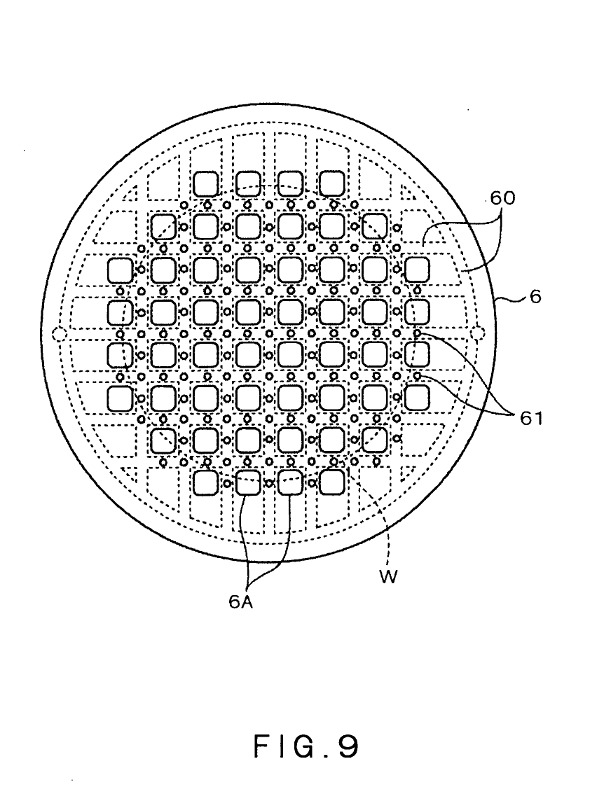

Next, one example of the film forming apparatuses for carrying out the film forming method of the present invention will be described with reference to FIGS. 8 and 9. In FIG. 8, reference numeral 51 designates a processing vessel (vacuum chamber) formed from, for example, aluminum, and a bottom portion of the processing vessel 51 is of a convex shape. A supporting table 52 is provided in the processing vessel 51, which is formed into, for example, a cylindrical shape and is adapted to horizontally support a semiconductor wafer (hereinafter, referred to as a “wafer”) W as a substrate. A foil-like electrode 52a is embedded in the supporting table 52 wherein the electrode 52a is connected with a direct current power source 54 via a switch 53. A temperature controller 52b, such as a heater, is also embedded in the supporting table 52, which is adapted for controlling a temperature of a face of the wafer W to be processed. Furthermore, means for transfer the wafer W to and from a carrier (not shown), for example, three lifting pins (not shown), are provided in the supporting table 52 to extend therethrough.

The supporting table 52 is supported by a supporting portion 55, and the supporting portion 55 extends up to the bottom portion of the processing vessel 51. The supporting table 52 and the supporting portion 55 can be raised and lowered by a lifting mechanism 56 provided proximally to the supporting portion 55, wherein a lower movable part of the supporting portion 55 is covered with a bellows 57 formed from stainless steel (SUS).

Above the supporting table 52, a first gas supply member 6 is provided, which is formed from an electric conductor, for example, aluminum, and which is constructed as, for example, a shower head having a generally circular shape when viewed in a plan view. In a face of the first gas supply member 6, which is opposed to the supporting table 52, multiple gas supply holes 61 are formed. In the processing vessel 51, a tubular member 62 (hereinafter, referred to as an “inner wall”), which is one size smaller than the processing vessel 51, is provided, and the first gas supply member 6 is provided at a top face of the inner wall 62.

The inner wall 62 has a gate for the wafer W (not shown) and a window (not shown) for observing a processing atmosphere, both being formed in a peripheral face thereof. In the upper portion of the inner wall 62, a heater 63, which is a first heater, is incorporated along the periphery. At two points along the periphery of the inner wall 62, gas flow passages 64 are formed to supply a gas from the bottom portion of the processing vessel 51 to lattice-like gas flow passages 60, which will be described below, in the first gas supply member 6. To the gas flow passages 64, gas supply passages 65 are connected, respectively.

To proximal ends of the gas supply passages 65, a supply source 66 for the film-forming gas, for example, the siloxane gas A, and a supply source 67 for the additive gas, for example, the methane gas, are connected via groups of gas supply equipment 68, 69, respectively. The groups of gas supply equipment 68, 69 include valves, mass flow controllers as flow rate controllers and the like, and are provided to control the gas supply, respectively. In this embodiment, a film-forming gas supply system is constructed with the film-forming gas supply source 66 and the group of gas supply equipment 68, while an additive gas supply system is constructed with the additive gas supply source 67 and the group of gas supply equipment 69.

In the interior of the first gas supply member 6, the lattice-like gas flow passages 60 are formed to be in communication with the gas supply holes 61, respectively. Also, in the first gas supply member 6, multiple openings 6A are formed to extend through the gas supply member 6. These openings 6A are provided to make plasma to be generated in a space above them pass through toward a space below the gas supply member 6, and are formed, for example, between the adjacent gas flow passages 60.

Above the first gas supply member 6, a gas supply passage 7, which is a second gas supply member, is provided. A proximal end of the gas supply passage 7 is connected with a gas supply source 71 of a helium (He) gas as a plasma forming gas via a group of gas supply equipment 72. The group of gas supply equipment 72 includes a valve, a mass flow controller as the flow rate controller and the like, and is adapted to control the gas supply.

Above the second gas supply member 7, a dielectric plate (microwave transmission window) 73 is provided, and an antenna portion 8 is provided on an upper portion of the dielectric plate 73 to closely contact with the dielectric plate 73. The antenna portion 8 includes a flat antenna main body 80 having a circular shape when viewed in a plan view, and a disk-like flat antenna member (slot plate) 81 which is provided on the bottom face of the antenna main body 80 via a lagging plate 83 and includes multiple pairs of slots formed therein. A radial line slot antenna (RLSA) is constructed with the antenna main body 80, the flat antenna member 81 and the lagging plate 83.

The antenna portion 8 is configured such that a microwave can be supplied thereto from a microwave generator 74 via a coaxial wave guide 84. A wave guide 84A disposed outside the coaxial wave guide 84 is connected with the antenna main body 80, and a central conductor 84B is connected with the flat antenna member 81 via an opening formed in the lagging plate 83. In this example, a plasma generating system is constructed with the microwave generator 74 and the antenna portion 8.

An exhaust pipe 85 is connected with the bottom portion of the processing vessel 51, and a proximal end of the exhaust pipe 85 is connected with a vacuum pump 87, as a vacuum exhaust device, via a pressure controller 86 comprising, for example, a butterfly valve or the like. In addition, in an inner wall of the processing vessel 51, a heater 88, which is a second heater, is provided. Furthermore, in a side wall of the processing vessel 51, a transfer port 75 for the wafer W, which can be opened and closed by a gate valve 89, is formed in a position opposed to the gate (not shown) formed in the inner wall 62.

The film forming apparatus further includes a controller 76 comprising, for example, a computer. The controller 76 is configured to control the groups of gas supply equipment 68, 69, 72, the pressure controller 86, the heaters 63, 88, the temperature controller 52b, the microwave generator 74, the switch 53 for electrostatic chuck of the supporting table 52, the lifting mechanism 56 and the like. The controller 76 includes a storage device which stores sequence programs for executing a series of processing steps, as will be described below, to be performed in the processing vessel 51, and a device for reading an instruction of each program and outputting a control signal to each section.

Subsequently, one example of the film forming method to be carried out by this embodiment will be discussed. First, the supporting table 52 is set at, for example, 350° C. by using the temperature controller 52b incorporated therein, and the temperature of the inner wall 62 is set at, for example, 200° C. by using the heater 63. In addition, the temperature of the inner wall of the processing vessel 51 is set at, for example, 90° C. by using the heater 88. Next, with a carrying arm (not shown), the wafer W is carried in the processing vessel 51 via the transfer port 75 and the gate of the inner wall 62, and is placed on the supporting table 52 by using the lifting pins (not shown) so as to be electrostatically chucked. In this case, a distance between the supporting table 52 and the bottom face of the first gas supply member 6 is set at 37 mm.

Thereafter, the SiCOH film 2 is formed, for example, as the interlayer dielectric film, on a surface of the wafer W. Namely, the pressure of the interior of the processing vessel 51 is reduced to a predetermined pressure, for example, 133 Pa (1 Torr), by vacuum evacuation, and the He gas is supplied through the gas supply passage 7 at a flow rate of 200 sccm while the sloxane gas A as the film-forming gas and the hydrogen gas as the additive gas are supplied from the first gas supply member 6 through the gas supply passages 65 at flow rates of 50 sccm and 10 sccm, respectively.

On the other hand, when a high-frequency (microwave) of, for example, 2.45 GHz and 2000 W, is supplied from the microwave generator 74, a microwave is propagated through the coaxial wave guide 84 in a TM mode, TE mode or TEM mode, and reaches the flat antenna member 81 of the antenna portion 8, and the microwave is then emitted toward a space spreading below via the dielectric plate 73 through the slot pairs, while it is propagated radially from a central portion to peripheral regions of the flat antenna member 81, via the central conductor 84B of the coaxial wave guide 84.

Consequently, the He gas is activated by energy of the microwave, thus plasma, which has high density and is uniform, is excited (generated) in the space above the first gas supply member 6. Thereafter, the resultant active species of He flow into the processing space below the first gas supply member 6 via the openings 6A of the gas supply member 6. Thus, the film-forming gas and the additive gas supplied into the processing space from the gas supply member 6 are activated (converted into plasma) due to the active species of He flowing into the space, as such the SiCOH film 2 is formed as previously described on the wafer W placed on the supporting table 52.

In this film forming method, it has been recognized that the SiCOH film 2 can be formed while maintaining the cyclic structure of the siloxane, by raising the temperature of the wafer W to, for example, 350° C., by temperature control due to the temperature controller 52b incorporated in the supporting table 52 and a heating effect provided to the wafer W from the plasma, setting the distance between the supporting table 52 and the bottom face of the first gas supply member 6 at 37 mm, keeping the atmosphere in the processing vessel 51 at a reduced pressure of 133 Pa (1 Torr), supplying a high-frequency (microwave) of, for example, 2.45 GHz and 2000 W, from the microwave generator 74, and converting the siloxane gas A and the hydrogen gas (additive gas) into plasma by using and the He gas as the plasma forming gas.

Because the temperature of the inner wall 62 surrounding the processing atmosphere and the temperature of the inner wall of the processing vessel 51 are set at 200° C. and 90° C., respectively, it has been found that higher in-plane uniformity can be obtained with respect to a film thickness of the wafer W. While an emission region of the plasma is more inside than the inner wall 62, the active species of plasma flow out of the inner wall 62 through the gate and the window of the inner wall 62, and reach the wall face of the processing vessel 51. Therefore, although the inner wall of the processing vessel 51 is located outside the inner wall 62, it constitutes a part of an environment for the film forming process. Accordingly, when the site of the inner wall of the processing vessel 51 is excessively cold, the film forming process becomes unstable, thus deteriorating the in-plane uniformity of the film thickness of wafer W. Therefore, the inner wall of the processing vessel 51 is heated. However, if the inner wall of the processing vessel 51 is heated to an excessively high temperature, the safety for workers becomes problematic. Thus, while it is preferred to control the inner wall of the processing vessel 51 at a higher temperature in regard to processing efficiency, it is controlled at approximately 90° C. In this manner, after the film forming process for the wafer W is ended, this wafer W is carried out of the processing vessel.

Subsequently, another example of the film forming method which is carried out by the film forming apparatus will be explained. First, the supporting table 52 is set at, for example, 350° C., and the temperature of the inner wall 62 is set at, for example, 200° C., by using the heater 63. In addition, the temperature of the inner wall of the processing vessel 51 is set at, for example, 90° C. Next, the wafer W is carried in the processing vessel 51 and is placed on the supporting table 52 and electrostatically chucked. In this case, the distance between the supporting table 52 and the bottom face of the first gas supply member 6 is set at 37 mm.

Thereafter, the SiCOH film 2 is formed, for example, as the interlayer dielectric film, on a surface of the wafer W. Namely, the pressure of the interior of the processing vessel 51 is reduced to a predetermined pressure, for example, 133 Pa (1 Torr), by vacuum evacuation, and the He gas is supplied through the gas supply passage 7 at a flow rate of 200 sccm while the siloxane gas A as the film-forming gas is supplied from the first gas supply member 6 through the gas supply passage 65 at a flow rate of 50 sccm.

On the other hand, when a high-frequency (microwave) of, for example, 2.45 GHz and 2000 W, is supplied from the microwave generator 74, the He gas is activated by energy of the microwave, thus plasma, which has high density and is uniform, is excited in the space above the first gas supply member 6. Thereafter, due to the resultant active species of He, the film-forming gas supplied into the processing space from the gas supply member 6 is activated (converted into plasma), as such the SiCOH film 2 is formed as previously described on the wafer W placed on the supporting table 52.

Subsequently, the hydrogen gas as the additive gas is supplied at a flow rate of 10 sccm, in exchange for the film-forming gas, from the first gas supply member 6 through the gas supply passage 65. Thereafter, when a high-frequency (microwave) of, for example, 2.45 GHz and 2000 W, is supplied from the microwave generator 74, the He gas is activated by energy of the microwave. Thus, the hydrogen gas is in turn activated by the active species of He, and the post-treatment is then carried out by irradiating plasma generated from the hydrogen gas onto the wafer W placed on the supporting table 52 and having the SiCOH film formed thereon. As a result, the Si dangling bonds in the SiCOH film are terminated by the H dangling bonds, as such the SiCOH film including significantly less dangling bonds can be obtained. In this manner, after the film forming process for the wafer W is ended, this wafer W is carried out from the processing vessel.

In the film forming apparatus described above, only the post-treatment for supplying the C dangling bonds and the H dangling bonds be generated by converting the additive gas into plasma may be provided to the wafer having the SiCOH film formed thereon by a separate film forming apparatus.

In the above example, while the interlayer dielectric film is illustrated, the SiCOH film may be used as another dielectric film than the interlayer dielectric film. In addition, the film-forming gas including organic silicon is not limited to the siloxane A, but trimethylsilane or a gas having a six-membered cyclic structure or eight-membered cyclic structure of siloxane may be used. As the additive gas, a silane gas may be used, in place of or in addition to, the paraffin hydrocarbon gas and/or the hydrogen gas.

### EXAMPLES

Experiment 1

### Example 1

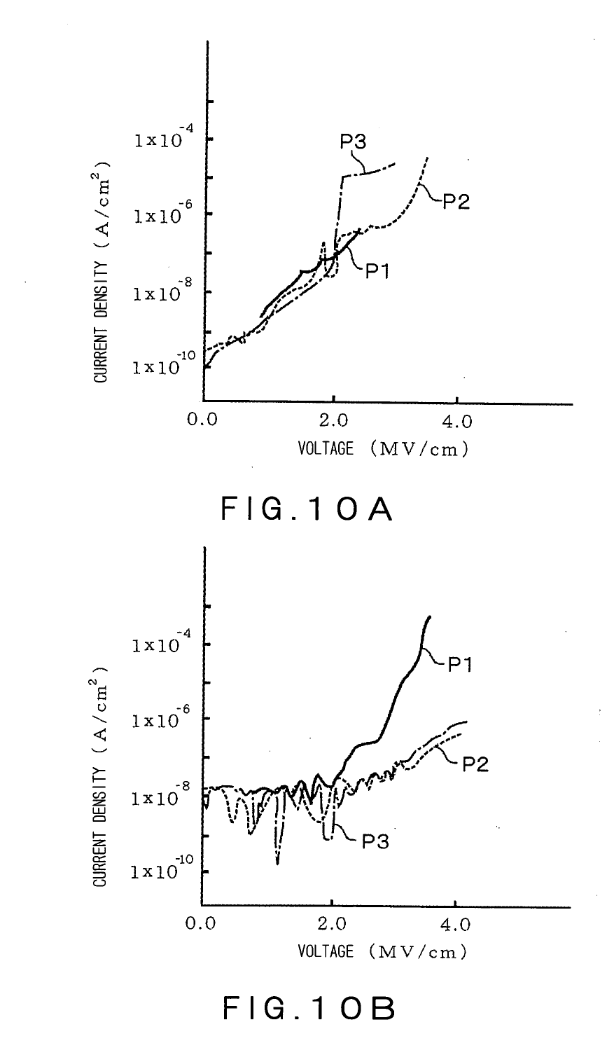

Using the apparatus described above, the SiCOH film 2 having a 200 nm thickness was formed under the aforementioned conditions. Thereafter, a voltage was applied to the so-formed SiCOH film 2, and density of current flowing at the time in the film was measured at three points on the wafer W. With respect to specific processing conditions, the siloxane gas A as the film-forming gas and the hydrogen gas as the additive gas were supplied into the processing vessel 51 from the first gas supply member 6 at flow rates of 50 sccm and 10 sccm, respectively, and the helium gas as the plasma forming gas was supplied into the processing vessel 51 from the second gas supply member 7 at a flow rate of 200 sccm. The microwave of 2.45 GHz and 2000 W was applied under the conditions that the supporting table temperature was 350° C., the distance between the supporting table 52 and the bottom face of the first gas supply member 6 was 37 mm, and the pressure in the processing vessel 51 was 133 Pa (1.0 Torr). The relationship between the current density and the voltage of this case is shown in FIG. 10A.

### Comparative Example 1

Using the apparatus described above, the SiCOH film 2 was formed under the same conditions of the Example 1 except that the additive gas was not added. Thereafter, a voltage was applied to the so-formed SiCOH film 2, and density of current flowing at the time in the film was measured at three points on the wafer W. The relationship between the current density and the voltage of this case is shown in FIG. 10B.

(Consideration)

In FIGS. 10A and 10B, the vertical axis designates the current density while the horizontal axis expresses the voltage, and a solid line corresponds to a point P1 on the wafer W, a dotted line expresses point P2 on the wafer W and a dashed line designates a point P3 on the wafer W, respectively.

In the Example 1 shown in FIG. 10A, as the applied voltage is increased up to approximately 2.0 MV/cm, the current density of the SiCOH film 2 is also increased gradually from approximately 1×10⁻¹⁰ A/cm² to 1×10⁻⁸ A/cm².

To the contrary, in the Comparative Example 1 shown in FIG. 10B, it was recognized that the current density of the SiCOH film was approximately 1×10⁻⁸ A/cm² on the average. Consequently, it is found that while the applied voltage is increased up to approximately 2.0 MV/cm, the current density of the SiCOH film of the Example 1 is lower than the current density of the SiCOH film 2 of the Comparative Example 1, thus a less amount of current is flowing in the SiCIH film of the Example 1. However, when the applied voltage exceeds 2.0 MV/cm, irregular changes are seen in the measured values of Example 1. Thus, it is understood that the film itself was broken.

The lower current density means that the leak current is less. Accordingly, it can be seen that the addition of the hydrogen gas can enhance the leak properties of the resultant SiCOH film.

Experiment 2

Next, a simulation concerning change of film properties due to the post-treatment of irradiating plasma generated from the additive gas to the SiCOH film after the formation of the SiCOH film was carried out. In this case, the simulation was carried out based on an assumption that an ethane gas (C₂H₆) as the additive gas and an Ar gas as the plasma gas are supplied to the SiCOH film containing the Si dangling bonds, in an imaginary processing vessel, so as to convert these gases into plasma. In this case, a calculation was performed, considering the following equations (1) and (2), and further assuming that the flow rates of the C₂H₆ gas and the Ar gas were 100 sccm and 400 sccm, respectively, and that the pressure in the processing vessel was 2 Torr.
C₂H₆+e→2CH3.+e (1)
Si.+CH₃.⇄Si—CH₃ (2)

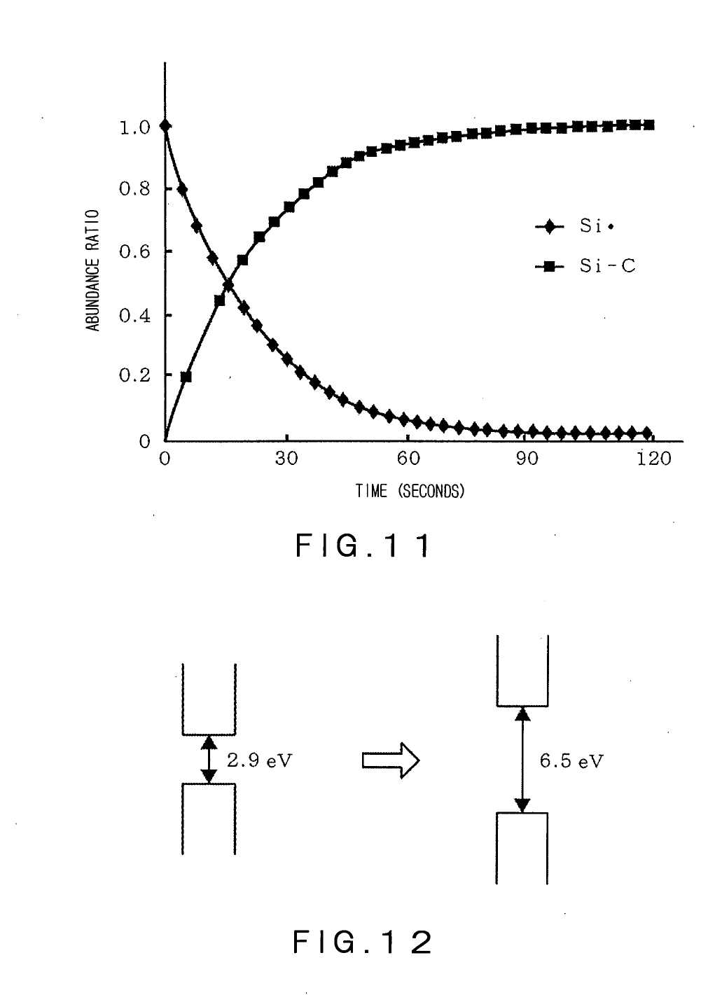

The results of this simulation are shown in FIG. 11. In the drawing, the horizontal axis designates time while the vertical axis expresses abundance ratios of the Si dangling bonds and Si—C bonds. The results concerning the Si—C bonds are shown by square plots, while the results concerning the Si dangling bonds (Si.) are shown by rhombic plots. From these plots, it is understood that the abundance ratio of the Si dangling bonds becomes smaller with time while the abundance ratio of the Si—C bonds becomes larger, and that the Si dangling bonds present on the initial stage are gradually terminated and reduced due to the C dangling bonds (CH₃.) generated from the ethane gas.

Another simulation concerning electron energy gap at this time was carried out. The energy gap refers to a size of a gap of an energy value that an electron can take in a steady state, and there is a remarkable correlation between the energy gap and electric properties. Namely, if the energy gap is smaller, an electric current is likely to flow, while if the energy gap is larger, the electric current is not likely to flow, thus reducing the leak current.

With this simulation, as shown in FIG. 12, results that the energy gap of the SiCOH film containing a great number of Si dangling bonds on the initial stage was 2.9 eV while the energy gap of the SiCOH film, which had been subjected to the post-treatment and to which the termination had been applied with the C dangling bonds (CH₃.), was raised up to 6.5 eV were obtained. From these results, it can be believed that since the leak current is reduced because the Si dangling bonds in the SiCOH film are terminated by the C dangling bonds and the electric current is not likely to flow, such a process as describe above can make the electric properties of the SiCOH film be significantly improved.

As previously described, the SiCOH film has a porous structure because it includes the cyclic structure of the siloxane and is formed by chained links of such cyclic structures. In addition, since such a siloxane cyclic structure is the six-membered cyclic and large in size, gaps or spaces formed in the film is relatively large. Therefore, the C dangling bonds (CH₃.) and the H dangling bonds (H.) are likely to penetrate into the gaps in the film, even after the formation of the film, as previously described with reference to FIG. 6. This may make it possible to terminate the Si dangling bonds, due to the post-treatment by using the additive gas, even after the formation of the SiCOH film.

From the above experiments, it can be recognized that due to the formation of the SiCOH film 2 by employing the siloxane gas A as the film-forming gas and the hydrogen gas as the additive gas and then converting these gases into plasma, or due to the post-treatment in which plasma generated from the ethane gas is irradiated to the SiCOH film after the formation of the SiCOH film by using the siloxane gas A as the film-forming gas and then converting the gas into plasma, the SiCOH film 2, which exhibits a reduced electric current and a lower dielectric constant, can be formed.

What is claimed is:

1. A film forming method comprising the steps of:
placing a substrate in a processing vessel; and
forming a carbon-hydrogen-added silicon oxide film on the substrate, by introducing a film-forming gas including an organic silicon and an additive gas including a paraffin hydrocarbon gas and/or a hydrogen gas into the processing vessel, and converting the film-forming gas and the additive gas into plasma.

2. The film forming method according to claim 1, wherein the film-forming gas including an organic silicon is a gas having a cyclic structure of a siloxane.

3. The film forming method according to claim 1, wherein the carbon-hydrogen-added silicon oxide film comprises a cyclic structure of the siloxane.

4. A film forming method comprising the steps of:
placing a substrate in a processing vessel;
forming a carbon-hydrogen-added silicon oxide film on the substrate, by introducing a film-forming gas including an organic silicon into the processing vessel, and converting the film-forming gas into plasma; and
post-treating the substrate having the carbon-hydrogen-added silicon oxide film formed thereon, by introducing an additive gas including a paraffin hydrocarbon gas and/or a hydrogen gas into the processing vessel, and converting the additive gas into plasma.

5. The film forming method according claim 4, wherein the film-forming gas including an organic silicon is a gas having a cyclic structure of a siloxane.

6. The film forming method according to claim 4, wherein the carbon-hydrogen-added silicon oxide film comprises a cyclic structure of the siloxane.

7. A film forming method comprising the steps of:
placing a substrate in a first processing vessel;
forming a carbon-hydrogen-added silicon oxide film on the substrate, by introducing a film-forming gas including an organic silicon into the first processing vessel, and converting the film-forming gas into plasma;
placing the substrate having the carbon-hydrogen-added silicon oxide film formed thereon in a second processing vessel;
post-treating the substrate having the carbon-hydrogen-added silicon oxide film formed thereon, by introducing an additive gas including a paraffin hydrocarbon gas and/or a hydrogen gas into the second processing vessel, and converting the additive gas into plasma.

8. The film forming method according claim 7, wherein the film-forming gas including an organic silicon is a gas having a cyclic structure of a siloxane.

9. The film forming method according to claim 7, wherein the carbon-hydrogen-added silicon oxide film comprises a cyclic structure of the siloxane.

10. A film forming apparatus comprising:
a processing vessel that receives a substrate therein;
a film-forming gas supply system configured to supply a film-forming gas including an organic silicon into the processing vessel;
an additive gas supply system configured to supply an additive gas including a paraffin hydrocarbon gas and/or a hydrogen gas into the processing vessel;
a plasma generating system configured to generate plasma in the processing vessel; and
a controller configured to control the film-forming gas supply system, the additive gas supply system, and the plasma generating system, to form a carbon-hydrogen-added silicon oxide film on the substrate, by introducing the film-forming gas and the additive gas into the processing vessel and converting those gases into plasma.

11. A film forming apparatus comprising:
a processing vessel that receives a substrate therein;
a film-forming gas supply system configured to supply a film-forming gas including an organic silicon into the processing vessel;
an additive gas supply system configured to supply an additive gas including a paraffin hydrocarbon gas and/or a hydrogen gas into the processing vessel;
a plasma generating system configured to generate plasma in the processing vessel; and
a controller configured to control the film-forming gas supply system, the additive gas supply system, and the plasma generating system, to form a carbon-hydrogen-added silicon oxide film on the substrate, by introducing the film-forming gas into the processing vessel and converting the film-forming gas into plasma, and then post-treat the substrate having the carbon-hydrogen-added silicon oxide film formed thereon, by introducing the additive gas into the processing vessel and converting the additive gas into plasma.
